(19) United States
(12) Patent Application Publication
(10) Pub. No.: US 2002/0117605 A1
(43) Pub. Date: Aug. 29, 2002

(54) Three-dimensional receiving and displaying process and apparatus with military application

(76) Inventor: Ray M. Alden, Raleigh, NC (US)

Correspondence Address: Ray M. Alden, 808 Lake Brandon Trail, Raleigh, NC, 27610, US

(21) Appl. No.: 10/132,331

(22) Filed: Apr. 24, 2002

Related U.S. Application Data
(63) Continuation-in-part of application No. 09/757,053, filed on Jan. 8, 2001.
(63) Continuation-in-part of application No. 09/970,368, filed on Oct. 2, 2001.

(51) Int. Cl. H01L 27/00

(52) U.S. Cl. 250/208.1

(57) ABSTRACT

The invention described herein represents a significant improvement for the concealment of objects and people. It integrates a three-dimensional encompassing display means with a three-dimensional encompassing light receiving means. Thousands of light receiving three-dimensional pixels and sending three-dimensional pixels are affixed to the surface of the object to be concealed Each receiving three-dimensional pixel divides light along the focal curve of one or more lens surfaces according to incident trajectory. Pixels along the focal curve of each lens surface each receive colored light from a respective section of the background around the object. In a first embodiment, individual receiving pixels detect this incident light electronically such that its trajectory, color and intensity are quantified. Light from each respective receiving pixel is then electronically reproduced by a corresponding respective sending pixel positioned along the focal curve of a second three-dimensional pixel so as to mimic the light with regard to trajectory, color, and intensity. In a second embodiment, incident light is divided into respective origination trajectories by a lens and then channeled by flexible light pipes to one or more respective opposite sides of the object where it is released at its original trajectory closely resembling its original intensity and color. The light which was incident on a first side of the object traveling at a series of respective trajectories is thus redirected and exits on at least one second side of the object according to its original incident trajectories. Both embodiments capture and emit light which mimics trajectory, color, and intensity in many concurrent directions such that an observer can “see through” the object to the background. In both embodiments, this process is repeated many times, in segmented pixel arrays, such that an observer looking at the object from any perspective actually “sees right through the object to its background” corresponding to the observer's perspective. The object having thus been rendered “invisible” to the observer.

### CROSS REFERENCE TO RELATED APPLICATIONS

This application is a Continuation-In-Part of application Ser. No. 09/757,053 filed Jan. 8, 2001 and of 09/970,368 filed Oct. 2, 2001.

### BACKGROUND FIELD OF INVENTION

The concept of rendering objects invisible has long been contemplated in science fiction. Works such as Star Trek and The Invisible Man include means to render objects or people invisible. The actual achievement of making objects disappear however has heretofore been limited to fooling the human eye with “magic” tricks and blending in type camouflage. The latter often involves coloring the surface of an object such as a military vehicle with colors and patterns which make it blend in with its surrounding.

The process of collecting pictorial information in the form of two-dimensional pixels and replaying it on two-dimensional monitors has been brought to a very fine art over the past one hundred years. Prior cloaking devices utilize two-dimensional pixels presented on a two-dimensional screen. The devices do a poor job of enabling an observer to “see through” the hidden object and are not adequately portable for field deployment.

More recently, three-dimensional pictorial “bubbles” have been created using optics and computer software to enable users to “virtually travel” from within a virtual bubble. The user interface for these virtual bubbles are nearly always presented on a two-dimensional screen, with the user navigating to different views on the screen. When presented in a three-dimensional user interface, the user is on the inside of these bubbles. These bubbles are not intended for use as nor are they suitable for cloaking an object.

The present invention creates a three-dimensional virtual image bubble on the surface of an actual three-dimensional object. It uses three-dimensional receivers or “cameras” and three-dimensional senders or “displays”. The “cameras” and “displays” are affixed to the surface of the military asset to be cloaked or rendered invisible. By contrast, observers are on the outside of this three-dimensional bubble. This three-dimensional bubble renders the object invisible to observers who can only “see through” the object and observe the object's background. The present invention can make military and police vehicles and operatives invisible against their background from nearly any viewing perspective.

This continuation in part describes more complex architecture to further expand the capabilities and fidelity of the inventor's prior disclosures.

### BACKGROUND DESCRIPTION OF PRIOR INVENTION

The concept of rendering objects invisible has long been contemplated in science fiction. Works such as Star Trek and The Invisible Man include means to render objects or people invisible. Prior Art illustrates the active camouflage approach used in U.S. Pat. No. 5,220,631. This approach is also described in “JPL New Technology report NPO-20706” August 2000. It uses an image recording camera on the first side of an object and a image display screen on the second (opposite) side of the object. This approach is adequate to cloak an object from one known observation point but is inadequate to cloak an object from multiple observation points simultaneously. In an effort to improve upon this, the prior art of U.S. Pat. No. 5,307,162 uses a curved image display screen to send an image of the cloaked object's background and multiple image recording cameras to receive the background image. All of the prior art uses one or more cameras which record two-dimensional pixels which are then displayed on screens which are themselves two-dimensional. These prior art systems are inadequate to render objects invisible from multiple observation points. Moreover, they are too cumbersome for practical deployment in the field.

The process of collecting pictorial information in the form of two-dimensional pixels and replaying it on monitors has been brought to a very fine art over the past one hundred years. More recently, three-dimensional pictorial “bubbles” have been created using optics and computer software to enable users to “virtually travel” from within a virtual bubble. The user interface for these virtual bubble are nearly always presented on a two-dimensional screen, with the user navigating to different views on the screen. When presented in a three-dimensional user interface, the user is on the inside of the bubble with the image on the inside of the bubble's surface.

Also known in the prior art are “three-dimensional” displays which attempt to display a first image stream to the right eye of observers and a second image stream to the left eye of observers. In actuality two streams can only achieve stereoscopic displays. Specifically, stereoscopic displays present the same two image streams to all multiple concurrent observers and are therefore not truly three-dimensional displays. The three-dimensional display as implemented using the technology disclosed herein provides many concurrent image streams such that multiple observers viewing the display from unique viewing perspectives each see unique image streams.

Using concurrent image receiving three-dimensional “cameras” and image sending “displays”, the present invention creates a three-dimensional virtual image bubble on the outside surface of an actual three-dimensional object. By contrast, observers are on the outside of this three-dimensional bubble. This three-dimensional bubble renders the object within the bubble invisible to observers who can only “see through the object” and observe the object's background. The present invention can make military and police vehicles and operatives invisible against their background from nearly any viewing perspective. It can operate within and outside of the visible range.

### BRIEF SUMMARY

The invention described herein represents a significant improvement for the concealment of objects and people. Thousands of directionally segmented light receiving pixels and directionally segmented light sending pixels are affixed to the surface of the object to be concealed. Each receiving pixel segment receives colored light from one point of the background of the object. Each receiving pixel segment is positioned such that the trajectory of the light striking it is known.

In a First, electronic embodiment, information describing the color, intensity, and trajectory of the light striking each receiving pixel segment is collected and sent to a corresponding sending pixel segment. Said sending pixel segment's position corresponding to the known trajectory of the said light striking the receiving pixel surface. Light of the same color and intensity which was received on one side of the object is thus sent on the same trajectory out a second side of the object. This process is repeated many times such that an observer looking at the object from nearly any perspective actually sees the background of the object corresponding to the observer's perspective. The object having been rendered “invisible” to the observer.

In a second, fiber optic embodiment, the light striking each receiving pixel segment is collected and channeled via fiber optic to a corresponding sending pixel segment. Said sending pixel segment's position corresponding to the known trajectory of the said light striking the receiving pixel surface. In this manner, light which was received on one side of the object is then sent on the same trajectory out a second side of the object. This process is repeated many times such that an observer looking at the object from nearly any perspective actually sees the background of the object corresponding to the observer's perspective. The object having been rendered “invisible” to the observer.

### Objects and Advantages

Accordingly, several objects and advantages of the present invention are apparent. It is an object of the present invention to provide a three-dimensional receiver of light (camera). It is an advantage of the present invention to provide a three-dimensional sender of light (display). It is an object of the present invention to provide an integration architecture to integrate the three-dimensional light receiver function together with the three-dimensional light sender function for concurrent real-time operation. It is an object of the present invention to create a three-dimensional virtual image bubble surrounding or on the surface of objects and people. Observers looking at this three-dimensional bubble from any viewing perspective are only able to see the background of the object through the bubble. This enables military vehicles and operatives to be more difficult to detect and may save lives in many instances. Likewise, police operatives operating within a bubble can be made difficult to detect by criminal suspects. The apparatus is designed to consume little or no energy, be rugged, reliable, and light weight.

The electronic embodiment can alternatively be used as a three-dimensional recording means and/or a three-dimensional display means. The present invention provides a novel means to record three-dimensional visual information and to playback visual information in a three-dimensional manor which enables the viewer of the recording to see a different perspective of the recorded light as he moves around the display surfaces while viewing the recorded image.

Further objects and advantages will become apparent from the enclosed figures and specifications.

### DRAWING FIGURES

FIG. 1 prior art illustrates the shortcomings of prior art using a two-dimensional image display.

FIG. 2 prior art illustrates the shortcomings of prior art using a two-dimensional image display with fuzzy logic.

FIG. 3 illustrates a deployed three-dimensional display of the present invention.

FIG. 4 illustrates an electronic three-dimensional electronic pixel cell of the present invention in the first embodiment.

FIG. 5 is an electronic pixel cell receiving light and cooperating with an electronic pixel cell sending light.

FIG. 6 depicts the cooperating 2-D pixels of FIG. 5 with controlling electronic archiecture.

FIG. 7a illustrates that pixel elements outside of the visible range can be integrated within electronic sending and receiving architecture.

FIG. 7b illustrates how prior art electronic sending architecture can be integrated into the present architecture.

FIG. 8a illustrates a CCD receiver and LCD sender providing a two-dimensional view of the prior art.

FIG. 8b shows a CCD receiving and focal curve LCD three-dimensional display of the present invention.

FIG. 8c shows a CMOS/APS receiver and LCD two-dimensional display of the prior art.

FIG. 8d shows a CMOS/Aps receiver and focal plane narrow field three-dimensional display of the present invention.

FIG. 9a depicts a means for alternately sending and receiving light in the sending mode.

FIG. 9b depicts a means for alternately sending and receiving light in the receiving mode.

FIG. 10a depicts a first architecture to drive the sending and receiving two-dimensional pixel of FIG. 9 in the sending/receiving mode.

FIG. 10b depicts the first architecture to drive the sending and receiving two-dimensional pixel of FIG. 9 in the receiving/sending mode.

FIG. 11a depicts a second architecture to drive the sending and receiving two-dimensional pixel of FIG. 9 in the sending/receiving mode.

FIG. 11b depicts the second architecture to drive the sending and receiving two-dimensional pixel of FIG. 9 in the receiving/sending mode.

FIG. 12 depicts a single three-dimensional pixel cooperating with multiple three-dimensional pixels.

FIG. 13a illustrates an array (plurality) of three-dimensional pixels.

FIG. 13b illustrates an array of three-dimensional pixels being observed by multiple concurrent observers.

FIG. 14 depicts multiple three-dimensional sending and receiving pixels on a first side of an asset cooperating with multiple three-dimensional sending and receiving pixels on a second side of an asset.

FIG. 15 illustrates the off axis limit of a single surface pixel lens of the present invention.

FIG. 16a depicts a single multi-surface pixel lens of the present invention.

FIG. 16b depicts an array (plurality) of multi-surface pixel lenses.

FIG. 16c illustrates the off axis limits of a single multi-surface pixel lens of the present invention in cross section.

FIG. 17 illustrates a single two-dimensional pixel sending light in conjunction with a CCD receiver.

FIG. 18a shows a multi-state flow chart for FIG. 10a.

FIG. 18b shows a multi-state flow chart for FIG. 10b.

FIG. 19 illustrates a flexible light pipe pixel cell of the present invention in the second embodiment.

FIG. 20 illustrates two cooperating three-dimensional pixel segments in the second embodiment.

FIG. 21a illustrates multiple cooperating three-dimensional pixel segments in the second embodiment.

FIG. 21b is a close-up of the sending/receiving injection surface architecture of the present invention in the second embodiment.

FIG. 22a is a soldier outfitted in a suit incorporating the present invention.

FIG. 22b is a cross section of the helmet and goggles of FIG. 22a.

FIG. 23a and FIG. 23b illustrate a three-dimensional pixel cell relationship testing process.

FIG. 24 illustrates the multiple surface relationships of a single pixel cell.

Numerals In Figures

30 first color changing asset

31 concurrent background X

31a light from point on background X

31b light from second point on background X

31c light from third point on background X

32a light from second light pipe

33 concurrent observer X

33a concurrent observer X′

35 first two-dimensional concurrently viewed surface

37 concurrent background Y

39 concurrent observer Y

39a concurrent observer Y′

41 light sensor

43 fuzzy logic concurrently viewed surface

45 second color changing asset

47 second concurrent background Y

49 three-dimensional concurrently viewed surface

51 three-dimensional pixel lens

51a seven surface lens

53 concurrent view Y

55 transparent asset

57 three-dimensional light sensors

57a second three-dimensional pixel cell

58 second three-dimensional pixel lens

58a two-dimensional CCD as light receiver

58b two-dimensional CMOS—APS as light receiver

59 concurrent view X

61 rigid focal curve shaped substrate

62 light from observer X

62a light to background X

62zz light received by helmet

63 two-dimensional sending pixel X

63a two-dimensional sending pixel with infrared

63b two-dimensional pixel cell with stacked architecture

63c first integrated sender/receiver two-dimensional pixel

63d three-dimensional first LCD two-dimensional pixel

63e second integrated sender/receiver two-dimensional pixel

64 two-dimensional receiving pixel

64a two-dimensional receiving pixel with infrared

65 two-dimensional sending pixel Y

65a second LCD two-dimensional pixel

66 two-dimensional LCD

67 wires to sending pixel X

68 wires from second three-dimensional pixel cell

69 wires to sending pixel Y

70 first three-dimensional pixel cell

70a LCD three-dimensional pixel on Focal Curve

70b LCD three-dimensional pixel on focal plane

70c three-dimensional pixel in display application

71 first light from sending pixel

71a light from second sending pixel

71b light from third sending pixel

71c light from fourth sending pixel

71n first off axis limit is observer space

72 two-dimensional light from LCD without lenses

75 electronic processing circuitry and logic

75a CCD/two-dimensional LCD electrical architecture and logic

75b CCD/three-dimensional LCD electrical architecture and logic

75c CMOS APS/two-dimensional LCD electrical architecture and logic

75d CMOS APS/three-dimensional LCD electrical architecture and logic

75e mirrored electronic processing circuitry and logic

77 third two-dimensional pixel

81 analog multiplexer

83 analog to digital converter

85 digital processor

87 conversion logic

89 digital to analog converter

91 analog demultiplexer

92 rigid wall

94 two-dimensional LCD pixel on focal plane

101a light sent to background

101zz light emitted from cloaking goggles

102 window layer

104 emission layer

106 depletion region

108 detection layer

110 forward bias lead through circuit

112 reverse bias lead through circuit

113 second switch in receiving mode

113a second switch in sending mode

114 first switch in sending mode

114a first switch in receiving mode

115 third switch in receiving mode

115a third switch in sending mode

117 fourth switch in sending mode

117a fourth switch in receiving mode

119 bistable multivibrator switch in state I

119a bistable multivibrator switch in state II

161 low pass filter

162 variable power source

163 green LED

164 band pass filter

165 upper energy band

167 red LED

168 lower energy band

170 blue LED

201 third integrated sender/receiver two-dimensional pixel

203 fourth integrated sender/receiver two-dimensional pixel

205 first wire bundle

206 second wire bundle

207 fifth integrated sender/receiver two-dimensional pixel

209 sixth integrated sender/receiver two-dimensional pixel

211 first focal curve off axis limit

212 lens plane

213 second focal curve off axis limit

215 seven surface lens plurality

217 first off axis lens surface

218 first off axis pixel array

219 second off axis lens surface

220 second off axis pixel array

221 third off axis lens surface

231 flexible light pipe bundle

233 flexible light pipe map board

235 second flexible light pipe bundle

236 upper adjoining cell

238 lower adjoining cell

251 first hexagonal lens

257 second hexagonal lens

258 three-dimensional light pipe pixel

259 plurality (array) of three-dimensional light pipe pixels

261 rigid focal curve substrate for light pipes

263 first focal curve light pipe injection lens

265 second focal curve light pipe injection lens

267 first flexible light pipe

269 second flexible light pipe

273 sixth focal curve light pipe injection lens

274 seventh focal curve light pipe injection lens

277 third focal curve light pipe injection lens

277a fourth focal curve light pipe injection lens

277b fifth focal curve light pipe injection lens

278 third flexible light pipe

301 Transparent Helmet

303 cloaking three-dimensional goggles

304 invisible armor

305 sensor joints

307 cloaked weapon

309 extreme off axis ray incident

311 extreme off axis ray exit

### DETAILED DESCRIPTION OF THE INVENTION

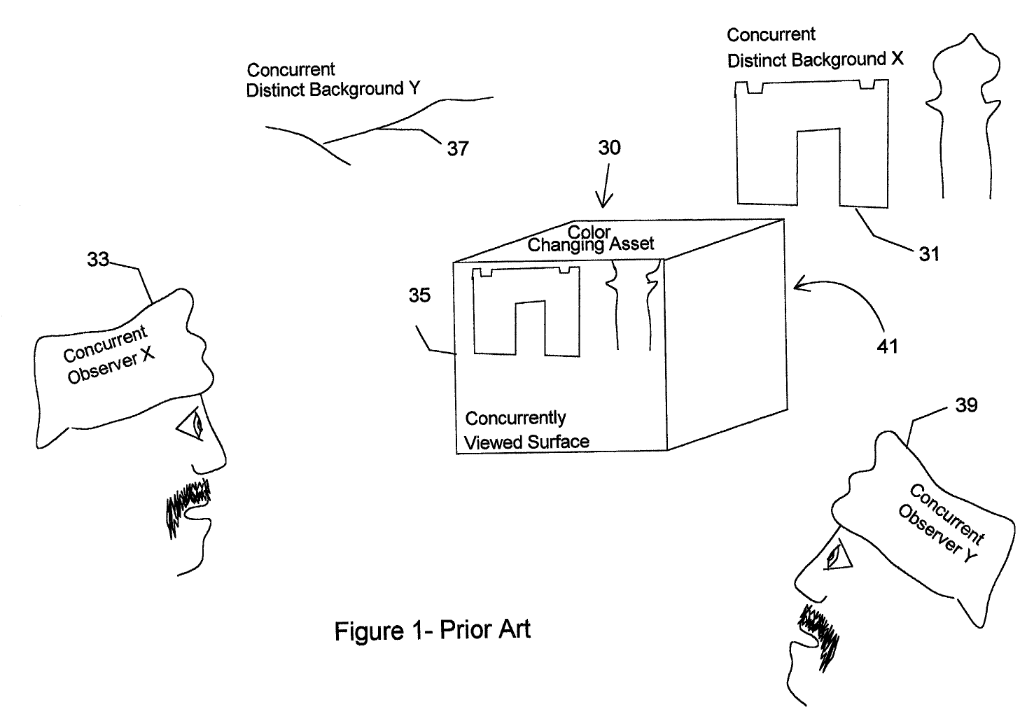

FIG. 1 prior art illustrates the shortcomings of prior art using a two-dimensional image display. A first color changing asset 30 has integrated a first two-dimensional concurrently viewed surface 35. The visual information display of 35 is detected by a light sensor 41 such as a CCD (not shown) on the opposite side of the asset. The image displayed on 35 is a reproduction of a concurrent background X 31. To a concurrent observer X 33, the 30 is well cloaked since the 35 matches the 31 against the background from 33's perspective. Meanwhile the 30 is not concealed from a concurrent observer Y 39 who can easily see the 30 since the 35 is incongruent with a concurrent background Y 37. From 39's perspective, the 30 stands out because the 35 image is totally incongruent with the background according to 39's perspective.

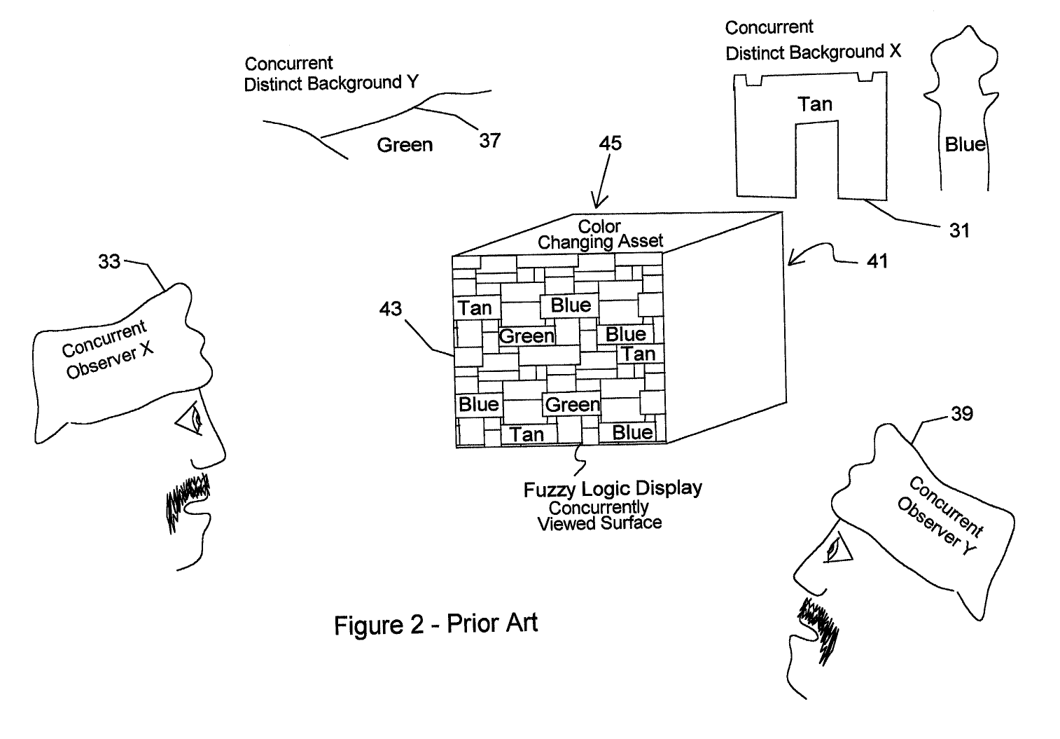

FIG. 2 prior art illustrates the shortcomings of prior art using a two-dimensional image display with fuzzy logic. A second color changing asset 45 uses a sensor such as 41 to detect background colors. A fuzzy logic concurrently viewed surface 43 presents a series of patches calculated to cause the asset to blend in with its background. A fuzzy logic computer program has calculated which patches of color to display in what pattern. To 33, the fuzzy logic pattern stands out against the background because it incorporates colors incongruent with the background according to 33's perspective. Also to 39, the fuzzy logic pattern stands out against the background because it incorporates colors incongruent with the background according to 39's perspective.

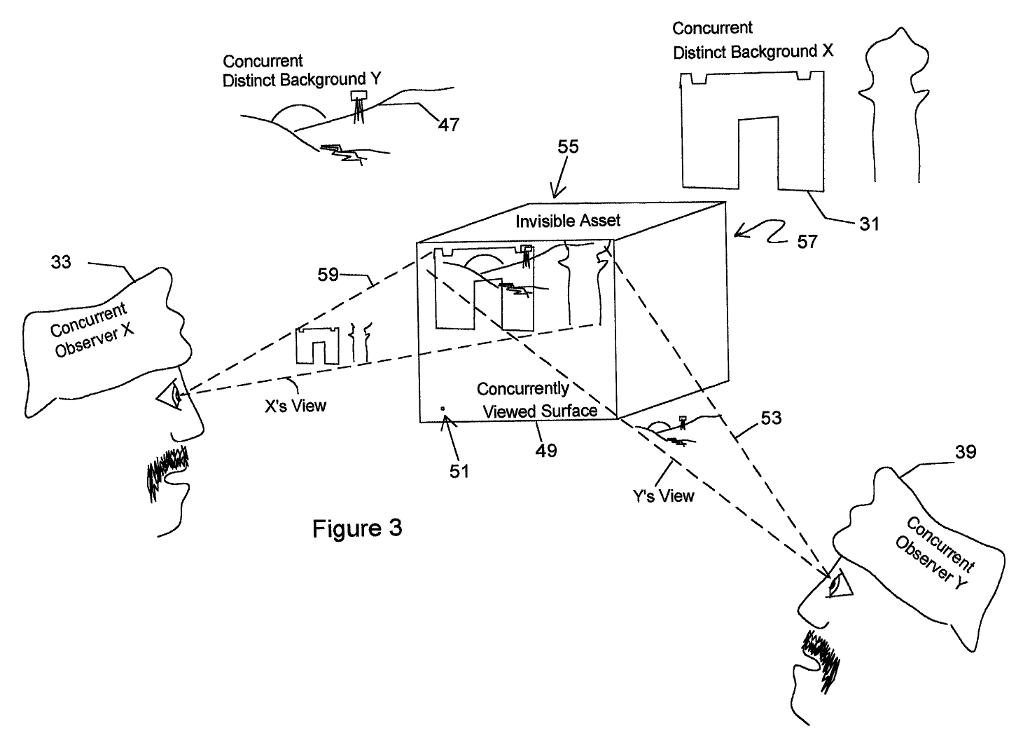

FIG. 3 illustrates a deployed three-dimensional display of the present invention. A transparent asset 55 uses three-dimensional light sensors 57 (later described) to present three-dimensional images representative of the panoramic background on a three-dimensional concurrently viewed surface 49. The 33 observer sees a concurrent view X 59 which accurately resembles background 31 from 33's perspective. Meanwhile on the same surface, 39 sees a concurrent view Y 53 which accurately resembles a second concurrent background Y 47 from 39's perspective. Thus two concurrent observers both see images on the surface of the same asset which are each respectively indistinguishable from the back ground from each of their relative perspectives. In practice many such observers from different perspectives will concurrently each see a unique view on the surface of the asset such that the asset is invisible from each of their relative perspectives. A three-dimensional pixel lens 51 is one of thousands of three-dimensional pixel cells that cover all surfaces of 55 to receive light and to send light as described herein.

First Embodiment—Electronic Implementation

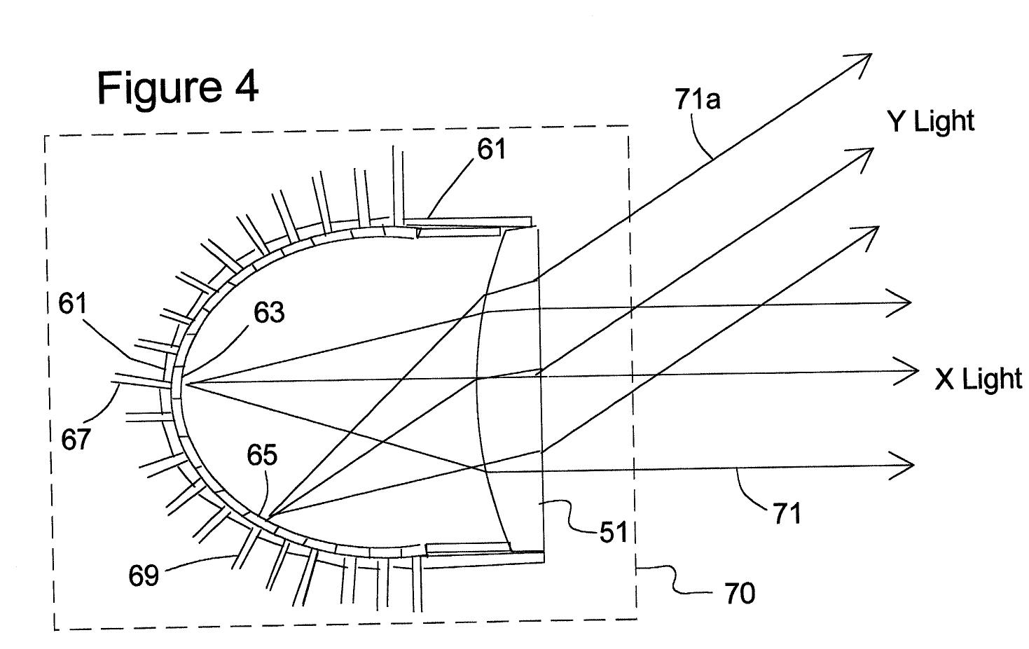

FIG. 4 illustrates a three-dimensional electronic pixel cell of the present invention in the first embodiment. The 51 is a single three-dimensional pixel cell lens as seen in FIG. 3. The 51 is a rigid hexagonal converging optic shown in cross section. Affixed to the 51 is a rigid focal curve shaped substrate 61. The 61 is an opaque rigid structure fabricated from metal or plastic to form the shape of the focal curve of the 51 lens. Deposited along the focal curve are an array (or plurality) of spots (two-dimensional pixels) which are capable of producing light, receiving light, or producing and receiving light. Light emitted from each pixel segment is sent on a specific trajectory by 51. For example, a two-dimensional sending pixel X 63 produces a first light from sending pixel 71 which is sent to the 33 of FIG. 3. Likewise, a two-dimensional sending pixel Y 65 produces a light from second sending pixel 71a which is sent to the 39 of FIG. 3. 63 is a light emitting material such as a semi-conductor, LED, and/or OLED which has been deposited on 61 in layers using masks in a combination of steps, so as to produce electrodes, p-type and n-type junctions, color filters, and/or color changing materials. Likewise, adjacent to 63 is a light receiving material such as a semi-conductor, photo diode which has been deposited on 61 in layers using masks in a combination of steps, so as to produce electrodes, p-type and n-type junctions, color filters, and/or color changing materials. Examples of matrix array deposition processes of materials that can efficiently convert electrons into photons (for sending light) of desirable wavelengths and of materials that can efficiently convert photons into electrons (for receiving light) being known in the fields of semi-conductors, LEDs, OLEDs, and photo-diodes. One company supplying technology to achieve the deposition being AIXTRON, Inc. of Aachen, Germany. Kodak of Rochester, N.Y., and Universal Display of Ewing, N.J. both being licensees of patents describing suitable OLED materials, layers, electronic controlling mechanisms, and deposition processes. Additionally, U.S. Pat. No. 5,583,351 Brown et al describes a semi-conductor deposition process. The only novel aspect of the deposition required herein is that it occurs on a focal curve shaped substrate instead of a flat substrate.

A wires to sending pixel X 67 supplies the electrical energy to produce the 71a. A wires to sending pixel Y 69 supplies the electrical energy to produce the 71.

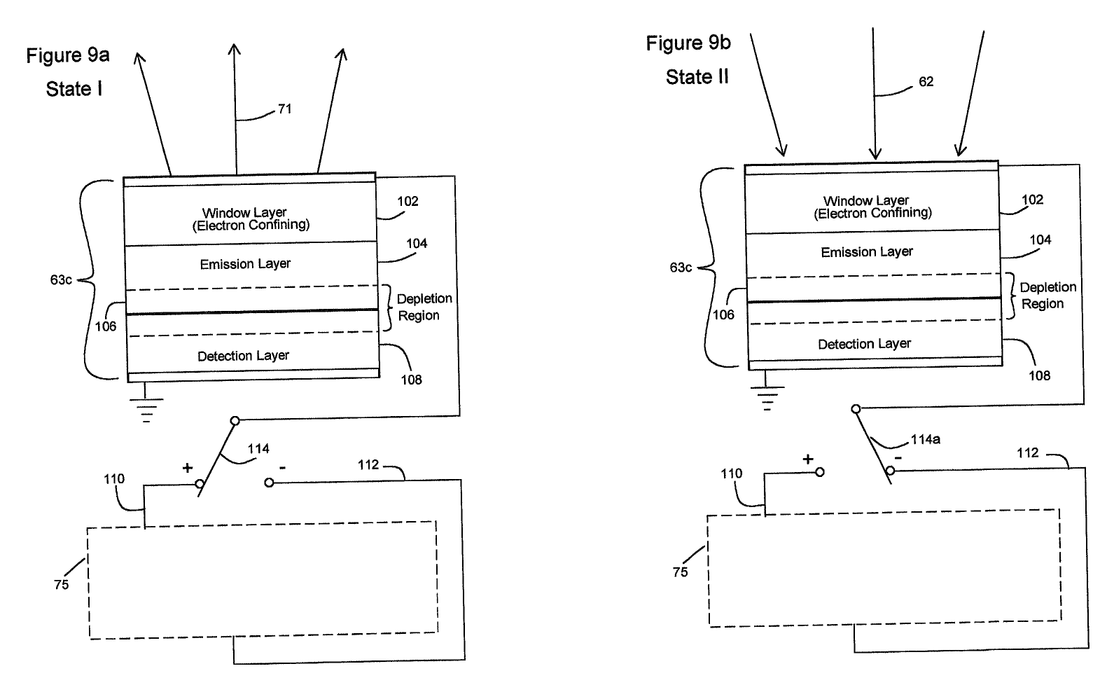

The first three-dimensional pixel cell 70 is a unit which combines light trajectory segmentation, light receiving elements, and light sending elements. Many thousands of similar units on the surface of the asset to be concealed, acting cooperatively through controlling electronic circuitry and logic render the asset invisible. The naming convention used here refers to 70 as a three-dimensional pixel while 63 is a two-dimensional pixel Each three-dimensional pixel such as 70 incorporates hundreds of two-dimensional pixels such as 63. This achieves the effect of segmenting the light in the observer field such that observers in different positions each observe different light from the same three-dimensional pixel. It should be noted that in all diagrams, light can flow in the reverse direction of what the arrows are indicating. This is literally true if the light emitting pixels also function as light sending pixels as is described in FIG. 9. If however, the light emitting pixels and the light sending pixels are distinct, then adjacent to 63 are receiving pixels that receive light from a trajectory nearly opposite that of the X Light. Thus the arrows can operate in nearly a reverse fashion.

If the 51 operates efficiently (discussed later) across a 0.5 steridians field in observer space, and if the system is to have a resolution of two degrees, then forty five receiving and forty five sending pixels are needed in each of 180 planes within the 70. (Each receiving and sending pixel representing adequate colors in the visible and non-visible ranges for suitable performance.) An arbitrary number of pixel segments are shown for illustrative purposes.

It should be noted that while only two sending pixels are shown sending light, in practice all of the sending pixels in 70 send light concurrently and all of the receiving pixels in 70 receive light concurrently.

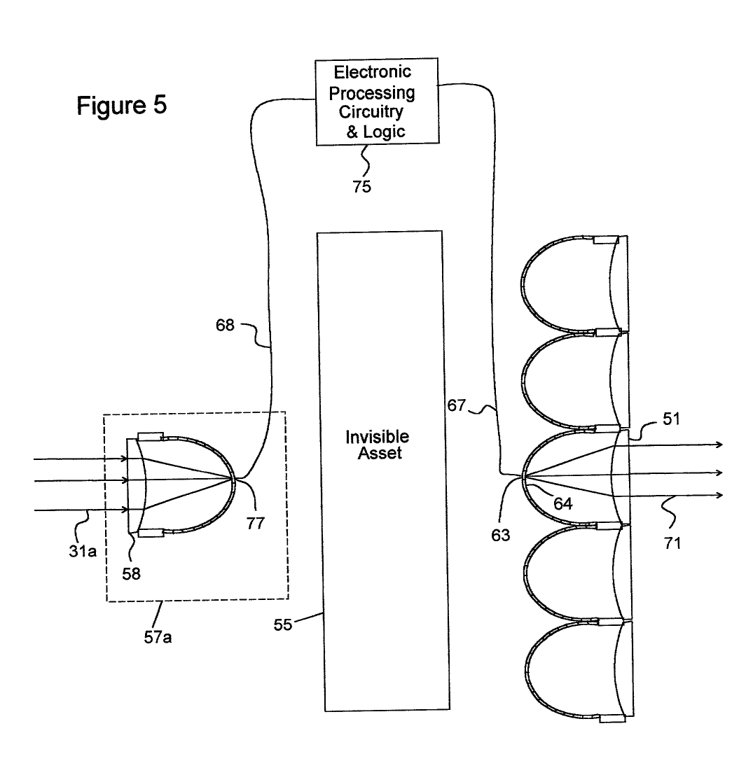

FIG. 5 is an electronic pixel cell receiving light and cooperating with an electronic pixel cell sending light. A second three-dimensional pixel cell 57a receives a light from point on background X 31a. 57a being identical to 70 but shown in a light receiving mode. In practice, all of the light receiving segments of 57a are concurrently receiving light, each from a different trajectory. A second three-dimensional pixel lens 58 causes the 31a to focus on a third two-dimensional pixel 77. 77 converts the 31a into an electric signal which is transferred via a wires from second three-dimensional pixel cell 68 to an electronic processing circuitry and logic 75 (discussed later). Said electric signal indicative of the red, green, and blue intensities in the received light. The 75 produces a corresponding electric current for red, green, and blue which are carried via 67 to 63 which emits light 71. Note that 71 mimics 31a in trajectory, color, and intensity. To an observer the 71 light appears to be coming from the back ground such that 55 appears is transparent. A two-dimensional receiving pixel 64 is shown adjacent to 63. In practice the 57a and the 70 switch between two states as described later. Note that a single receiving pixel such as 77 within a three-dimensional pixel has a corresponding relationship with a single sending pixel such as 63 within a corresponding pixel.

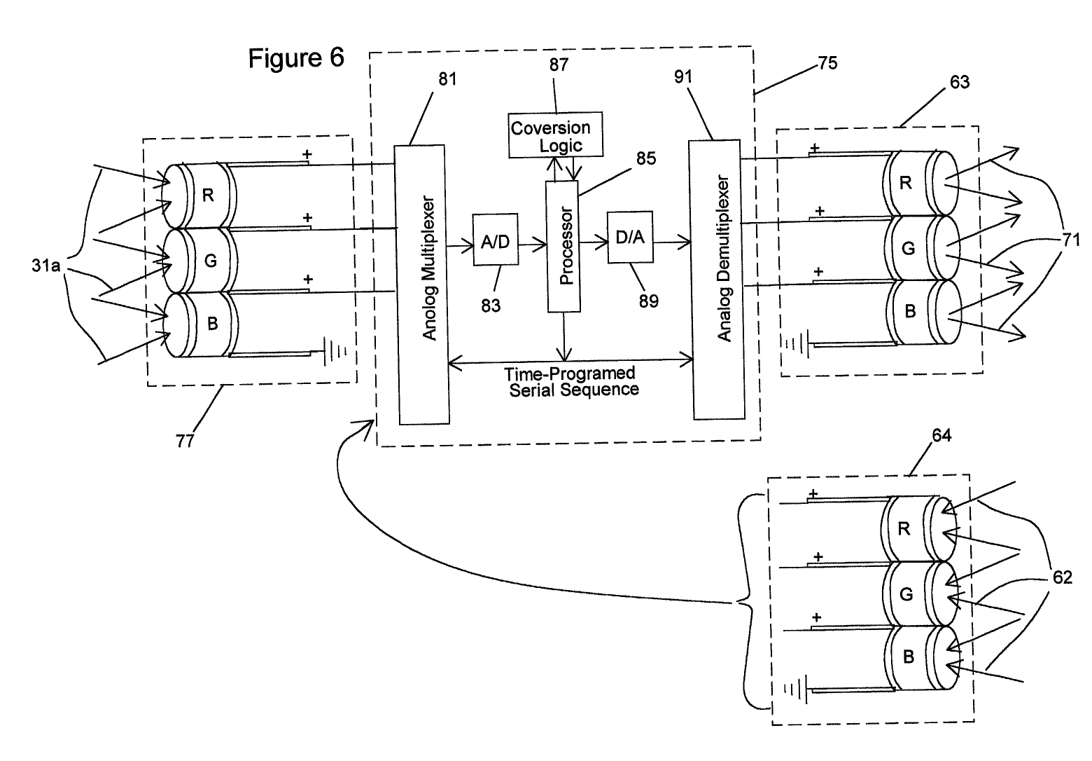

FIG. 6 depicts the cooperating 2-D pixels of FIG. 5 with controlling electronic architecture. 71 is shown to have red, green, and blue sections each of which are receiving light 31a. The 31a is converted into corresponding electron currents indicative respectively of red, green, blue light intensity. The current being received by an analog multiplexer 81. The 81 is monitored in a time-programmed serial sequence according to a clock and a digital processor 85. The electrical signal is transferred to an analog to digital converter 83 so as to be read by 85. 85 employs a conversion logic 87 to convert the received digital signal to an appropriate response digital signal. The logic takes into account the receiving inefficiencies and sending inefficiencies to ensure that the true intensity of 31a is translated into an accurate representation (mimic) at 71. The processor accordingly controls a digital to analog converter 89 to produce a corresponding electric signal carried through a analog demultiplexer 91 to power each element of the 63 such that red, green, and blue light is produced at 71 to mimic 31a. The 71 light exiting on the same trajectory as the 31a as previously discussed. The 64 receives a light from observer X 62 which is processed identically as described above although on a subsequent sequence.

To improve sequencing speed, in practice, multiple units similar to 75 can be used to cloak the same asset in faster serial sequencing cycles. Much prior art is dedicated to the electronic architecture of light receiving arrays such as CCDs, CMOS, and photodiode arrays which are suitable for use herein. Likewise, much prior art is dedicated to processing electronic signals from such arrays and to sending corresponding signals to control displays such as LED displays, OLED displays, and LCD displays. Such prior art being suitable for use herein. Some examples of prior art electronic architecture are described in works such as; Electronic Measuring Systems, 2^{nd} ed, VanPutten, A. 1996, Institute of Physics, London; Image Processing System Architecture, Kittler, J. and Duff, M., 1985, Research Studies Press, Hertfordshire, England; Digital Control Systems, Houpis, C., Lamont, G., 1992, McGraw-Hill, New York; and Digital and Analog Data Conversions, Malmstadt, H., Enke, C., Crouch, S., 1973, W. A. Benjamin, Inc. Menlo Park.

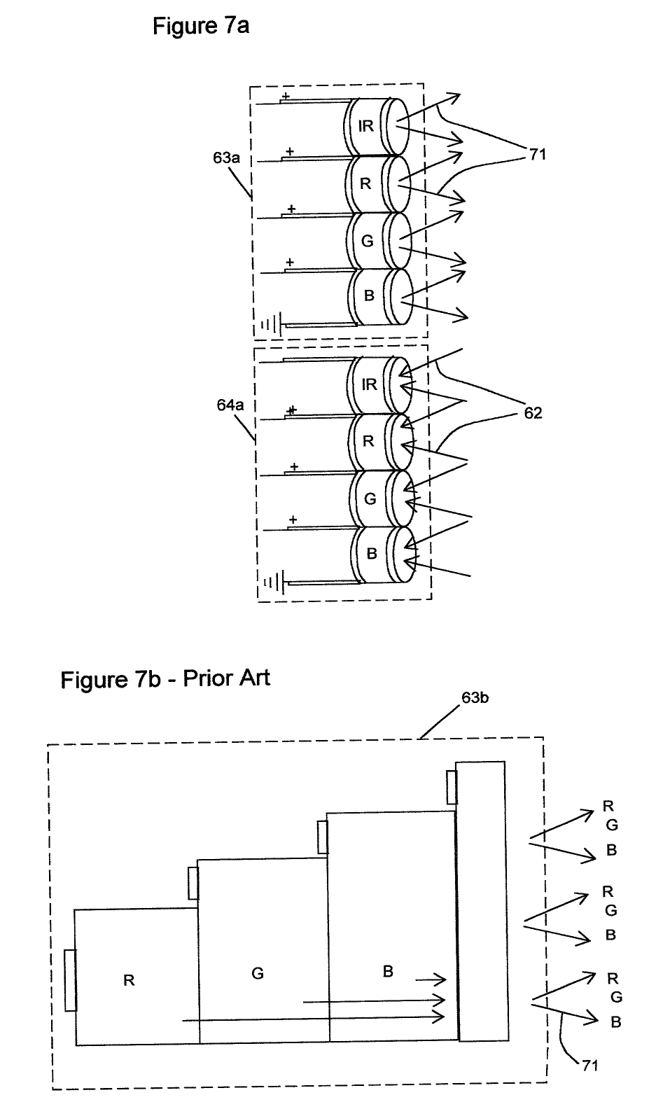

FIG. 7a illustrates that pixel elements outside of the visible range can be integrated within electronic sending and receiving architecture. A two-dimensional sending pixel with infrared 63a is integrated into the sending pixel to send infrared electromagnetic energy representative of that received. Also a two-dimensional receiving pixel with infrared 64a receives infrared light within 62. In practice, enemy night vision and infrared sensing detectors within weapons aiming systems generally operate within specific known IR bands. It is therefore possible to fit IR receivers and senders within the three-dimensional cloaking pixel architecture such that the asset is cloaked within these specific bands as well as within the visible range. The 63a pixel can replace the 63 pixel and the light to background X 62a pixel can replace the 62 pixel.

FIG. 7b illustrates how prior art electronic sending architecture can be integrated into the present architecture. A two-dimensional pixel cell with stacked architecture 63b produces the 71 light with red, green and blue components from its entire surface area. 63b describes the prior art of U.S. Pat. No. 5,739,552 Kimura et al. The 63b pixel architecture can replace the 63 architecture to improve efficiency.

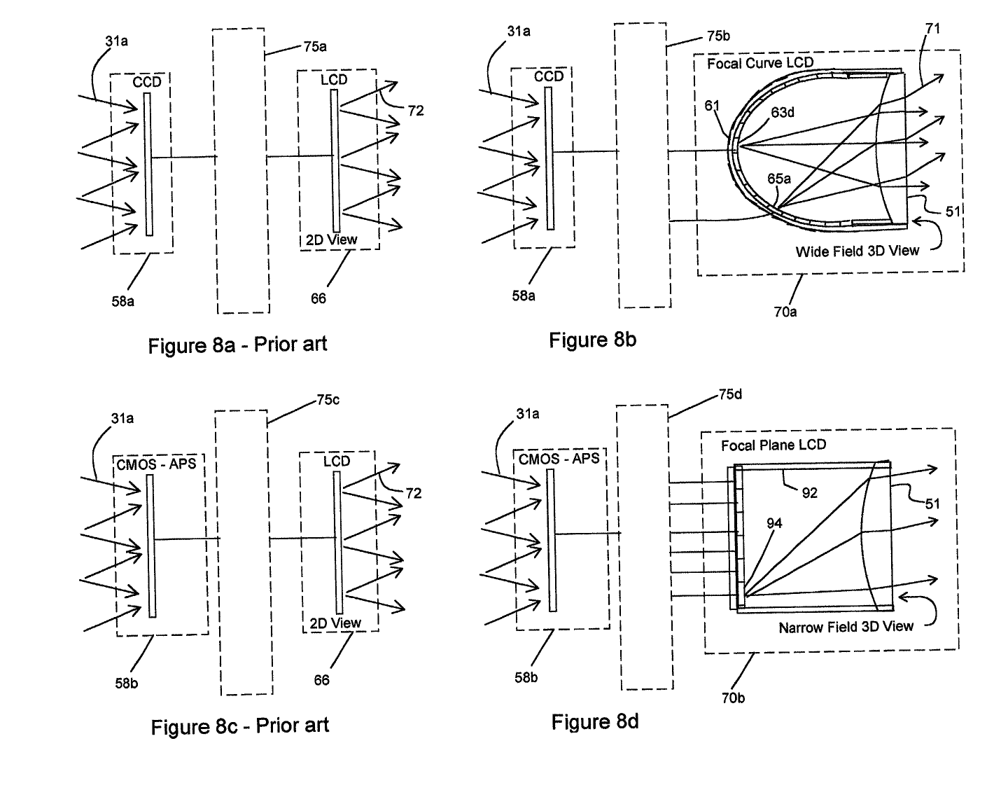

FIG. 8a illustrates a CCD receiver and LCD sender providing a two-dimensional view of the prior art. A two-dimensional CCD as light receiver 58a receives light from the background which is processed by a CCD/two-dimensional LCD electrical architecture and logic 75a and sent to a two-dimensional LCD 66 which produces a two-dimensional light from LCD without lenses 72. Light produced by this method is represented in FIGS. 1 and 2. Note that this architecture lacks the lens in front of the sending side and therefore can not produce true three-dimensional images.

FIG. 8b shows a CCD receiving and focal curve LCD three-dimensional display of the present invention. The 58a can be used with the present invention, particularly when several CCDs in combination sense information from the background. A CCD/three-dimensional LCD electrical architecture and logic 75b combine the information from multiple CCDs in computer modeling software to produce light from an LCD three-dimensional pixel on Focal Curve 70a 70a is the present invention with an LCD on the focal curve substituted for the semiconductor display pixels on the focal curve. Note that the combination of having 51 and having the sending LCD on the focal curve enables the LCD sender to operate as a three-dimensional pixel with light segmented within the observer space.

FIG. 8c shows a CMOS/APS receiver and LCD two-dimensional display of the prior art. A two-dimensional CMOS—APS as light receiver 58b receives light 31a from the background. The signal produced by 58b is processed by a CMOS APS/two-dimensional LCD electrical architecture and logic 75c and a corresponding signal is sent to 66. This system has no lens and is not capable of operating as a three-dimensional pixel.

FIG. 8d shows a CMOS/Aps receiver and focal plane narrow field three-dimensional display of the present invention. A CMOS APS/three-dimensional LCD electrical architecture and logic 75d processes the electronic signal from 58b and preferably from other similar CMOS/APS's and sends corresponding signals to an LCD three-dimensional pixel on focal plane 70b. The light sending LCD in 70b is on the focal plane of lens 51. This produces a three-dimensional view over a more narrow portion of the user space than does placing the LCD on the focal curve (as in FIG. 8b). A rigid wall 92 connects the 51 to the LCD and a two-dimensional LCD pixel on focal plane 94 is a sample pixel from the LCD.

FIG. 9a depicts a means for alternately sending and receiving light in the sending mode. A first integrated sender/receiver two-dimensional pixel 63c is shown in the sending state (State I). The 71 is produced when a first switch in sending mode 114 is in a first position, thus causes first forward bias within the 63c and connection on the first side of 75.

The 63c can be used in place of the 63. Examples of prior art patents describing the means to perform receiving of light and sending of light in one unit are described in the prior art including U.S. Pat. No. 5,097,299 Donhowe et al, U.S. Pat. No. 4,989,051 Whitehead et al, U.S. Pat. No. 4,948,960 Simms et al, and U.S. Pat. No. 3,952,265 Hunsperger to name a few.

FIG. 9b depicts a means for alternately sending and receiving light in the receiving mode. The 63c is shown in the receiving state (State II). A 114a first switch in receiving mode causes a reverse bias within the 63c and causes the a connection on the second side of 75. FIGS. 9a and 9b illustrate the 63c operating alternately between a light sending state and a light receiving state. Arrays of such semiconductors appropriately doped and/or filtered for red, green, and blue light receiving/emission operate both efficiently and at high fidelity for producing accurate three-dimensional sensing and representation of the two pi steridians background surrounding a cloaked asset. The 63c architecture enables tighter packing of both sending and receiving pixel segments within each three-dimensional pixel.

10a depicts a first architecture to drive the sending and receiving two-dimensional pixel of FIG. 9 in the sending/receiving mode. A second integrated sender/receiver two-dimensional pixel 63e is identical to 63c except that it operates in the opposite state so as to cooperate with 63c. When a second switch in receiving mode 113 is in a first position, 31a light is received by 63e which coverts it into an electric current, which is processed by 75 which produces a corresponding current sent through 114 to power 63c and produce 71.

10b depicts the first architecture to drive the sending and receiving two-dimensional pixel of FIG. 9 in the receiving/sending mode A second switch in sending mode 113a reverses the circuit together with 114a such that 63e now sends light corresponding to the light sensed by 63c. Thus a light sent to background 101a is produced in response to 62.

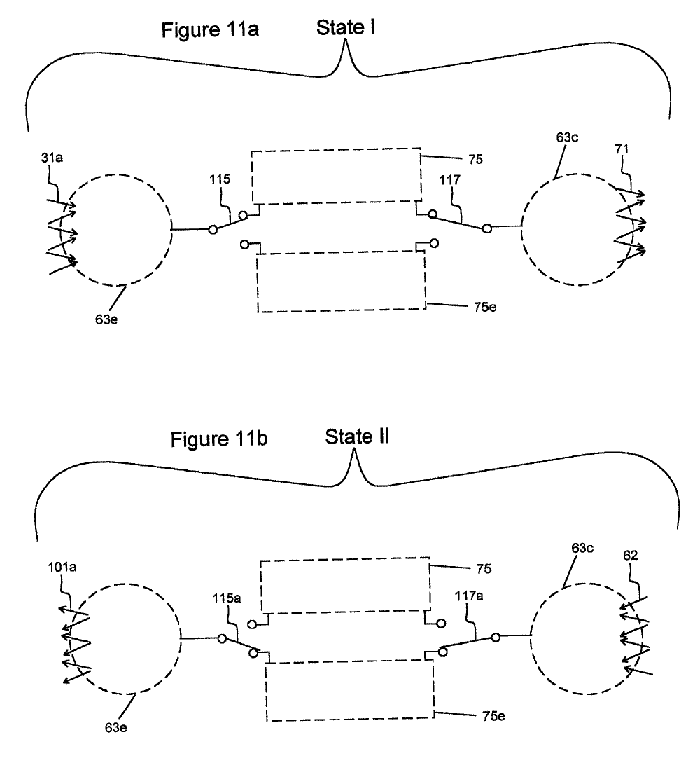

FIG. 11a depicts a second architecture to drive the sending and receiving two-dimensional pixel of FIG. 9 in the sending/receiving mode. A mirrored electronic processing circuitry and logic 75e is identical to 75 except reverse. Thus switching between 75 and 75e as in FIG. 11b enable the 63c and the 63e to operate as both receivers and senders of light alternately.

FIG. 11b depicts the second architecture to drive the sending and receiving two-dimensional pixel of FIG. 9 in the receiving/sending mode.

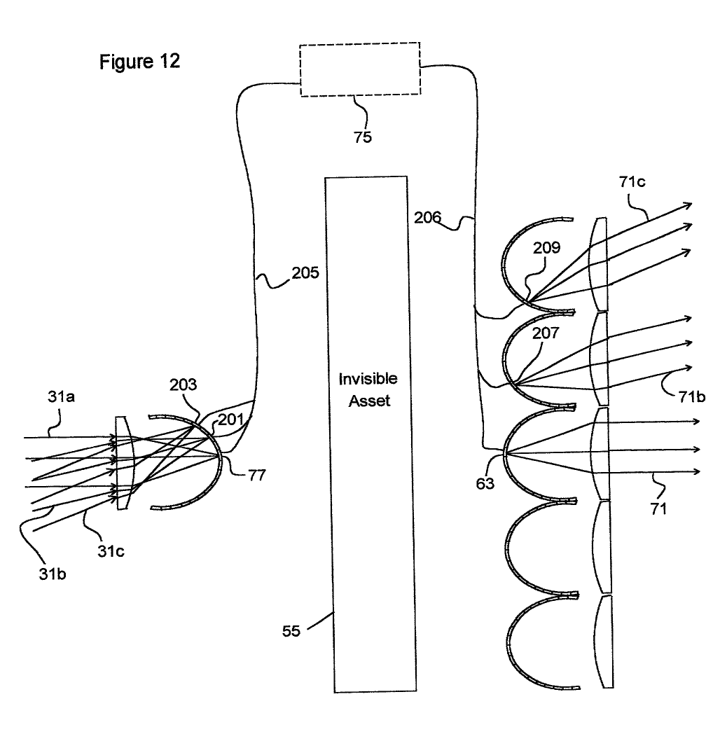

FIG. 12 depicts a single three-dimensional pixel cooperating with multiple three-dimensional pixels. 31a light from a first trajectory is sensed by 77 which sends a corresponding current via first wire bundle 205 to 75 where it is processed. A corresponding current is sent via second wire bundle 206 to 63 where it emerges as 71. The 71 resembling the 31a in trajectory, color and intensity. Note that in a rigid three-dimensional cloaking system, the relationship between 77 and 63 is a fixed one. For example, light received by 77 will always be responded to by 63. (The invention described herein applicable to both rigid and non-rigid systems as later described.) Meanwhile, a light from second point on background X 31b is received by a third integrated sender/receiver two-dimensional pixel 201. The 201 produces an electric current which is processed by 75 and responded to by a fifth integrated sender/receiver two-dimensional pixel 207 which emits a light from third sending pixel 71b. The 71b mimics the 31b in trajectory, color, and intensity. Similarly, a light from third point on background X 31c is sensed by a fourth integrated sender/receiver two-dimensional pixel 203. The 203 sends a current to 75 which produces a corresponding current powering a sixth integrated sender/receiver two-dimensional pixel 209. The 209 producing a light from fourth sending pixel 71c which mimics 31c in intensity, color and trajectory. Thus one three-dimensional pixel has corresponding relationships with many other three-dimensional pixels. In practice each three-dimensional pixel corresponds with hundreds of pixels. Each constituent two-dimensional pixel having a relationship with one other two-dimensional pixel By reproducing light many thousands of times in this manner, the 55 is rendered invisible to observers located in any viewing position relative to the 55.

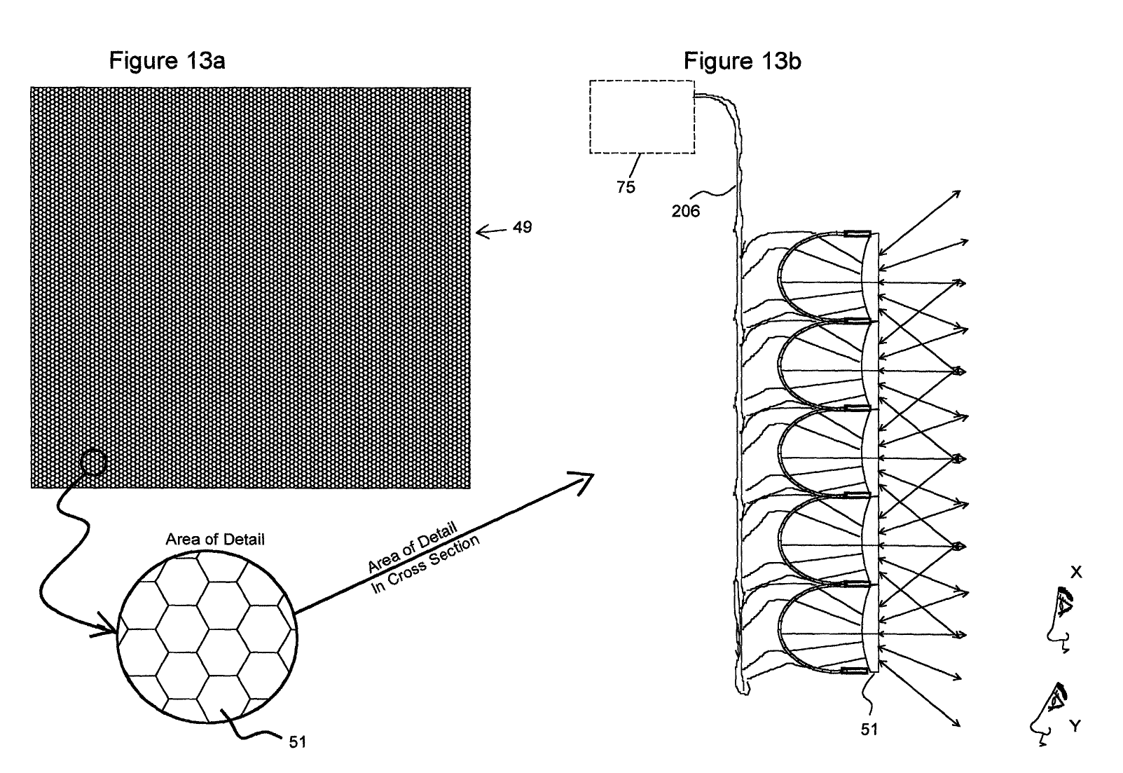

FIG. 13a illustrates an array (plurality) of three-dimensional pixels. In effect the 49 in this illustration is a three-dimensional display which happens to be on the surface on an asset. Such a display can also be used as a television monitor, computer screen, or movie theater screen. It is comprised on many hexagonal pixels each of which has a 51 lens which segments outgoing light. As a three-dimensional light receiver, each 51 also segments incoming light.

FIG. 13b illustrates an array of three-dimensional pixels being observed by multiple concurrent observers, Though an observer at point X and an observer at point Y both look at the same 51 lens surface, each observer sees a different color being omitted. This is because the out going trajectories of light are segmented according to focal point along the focal curve as previously described. Each pixel cell also receives light from segmented trajectories.

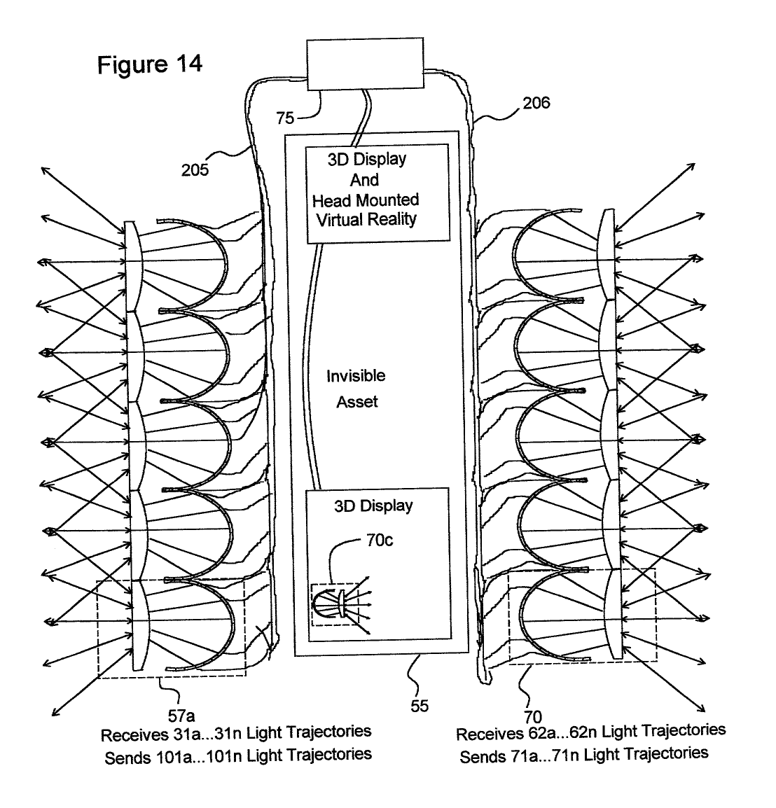

FIG. 14 depicts multiple three-dimensional sending and receiving pixels on a first side of an asset cooperating with multiple three-dimensional sending and receiving pixels on a second side of an asset. Note that in the electronic embodiment, the three-dimensional information that is processed can also be used to drive a three-dimensional viewing display for occupants of 55. For example, a three-dimensional pixel in display application 70c inside of the 55 produces light output for occupants within 55. (In practice many such pixels within the asset are used in combination to produce a display.) 70c however need not have any light receiving capability. Interior walls of the 55 can have corresponding displays affixed thereto or alternately occupants can wear position sensing displays which produce a virtual view “through the sides” of the asset. 57a detects light from 31n trajectories where n is the number of sensors positioned along the focal curve. 57a sends light to 101n trajectories where n is the number of emitters positioned along the focal curve. 70 detects light from 31n trajectories where n is the number of sensors positioned along the focal curve. 70 sends light to 101n trajectories where n is the number of emitters positioned along the focal curve.

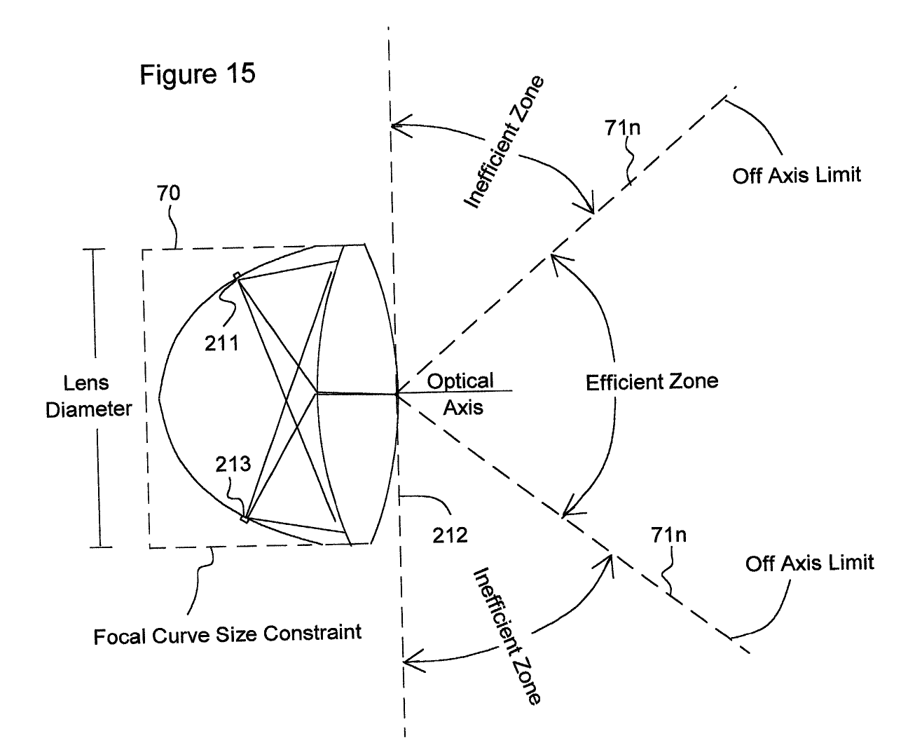

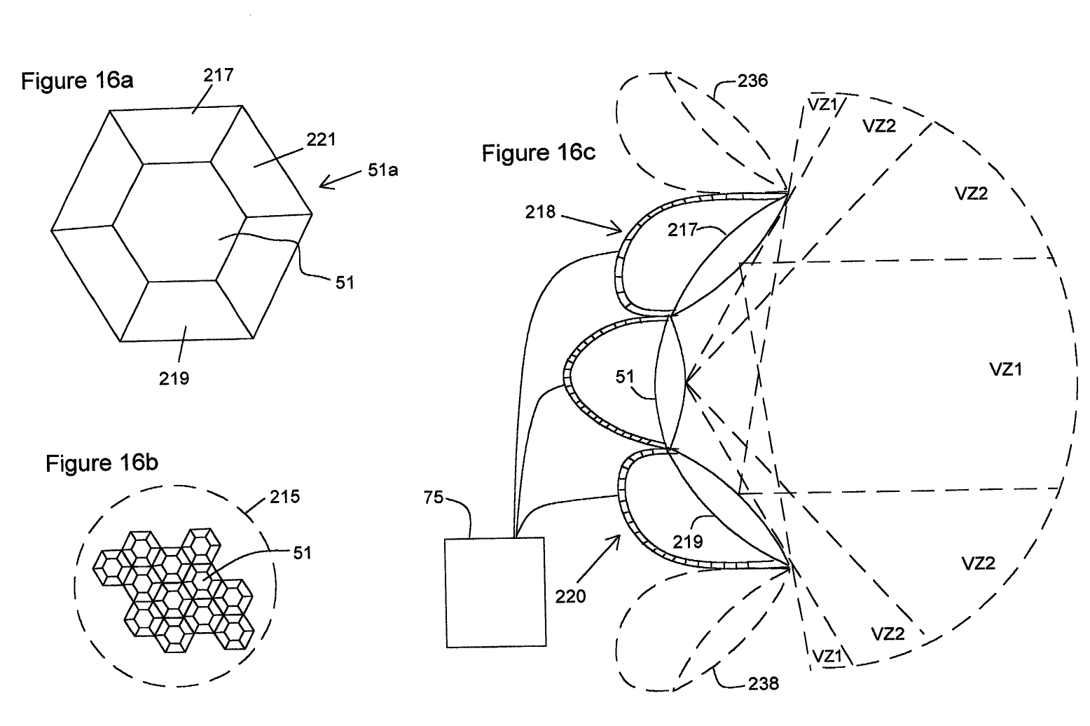

FIG. 15 illustrates the off axis limit of a single surface pixel lens of the present invention. At a first focal curve off axis limit 211, the three-dimensional pixel cell is at its limit. If further pixels were placed higher up the curve, light they produce will not efficiently pass through the lens. One constraining factor is that the diameter of the three-dimensional pixel can not be greater than the diameter of the lens. A first off axis limit in observer space 71n is a circle in user space. An observer within the efficient zone sees light emitted by the emitters on the focal curve and the asset is concealed but an observer in the inefficient zone can not see any light emitted from emitters on the focal curve and instead can see the lens and therefore the asset is not concealed. This problem is a constraint of the architecture discussed heretofore where all of the lens surfaces on a given side of the asset have had parallel optical axes. The problem is solved when some of the optical surfaces have different optical axes such as in FIG. 16c.

FIG. 16a depicts a single multi-surface pixel lens of the present invention. A seven surface lens 51a has at its center the 51 as its first surface. In additional to 51 the 51a has multiple additional optical surfaces which have optical axes not parallel to that of 51's. A first off axis lens surface 217, a second off axis lens surface 219, and a third off axis lens surface 221 each being examples of optical surfaces residing in non-parallel planes.

FIG. 16b depicts an array (plurality) of multi-surface pixel lenses. The 51a type lenses are arrange in arrays as were those previously discussed (as in FIG. 13a). A seven surface lens plurality 215 being a small sample of how the 51a's fit together. The 215 being manufactured from a semi-rigid material transparent in desirable ranges of electromagnetic radiation. Plastic panels can be readily manufactured and affixed to the surface of assets.

FIG. 16c illustrates the off axis limits of a single multi-surface pixel lens of the present invention in cross section. Note that surface 217 has its own focal curve pixel set, a first off axis pixel array 218, 51 has its own focal curve set, and 219 has its own focal curve pixel set, a second off axis pixel array 220. Each pixel on each focal curve operates as previously described herein. While each of the surfaces has similar limits to those described in FIG. 15, when operated together the lens produces excellent cloaking across a pi steridian observer field. The observation field can be broken down into two types of zones. Observers in the VZ1 zone see emitted light from 100% of the observable lens surface. Observers in the VZ2 zone see emitted light from approximately 80% of the observable lens surface and no emitted light from approximate 20% of the observable lens surface. It is believed that the VZ2 zones can be eliminated with further tweaking.

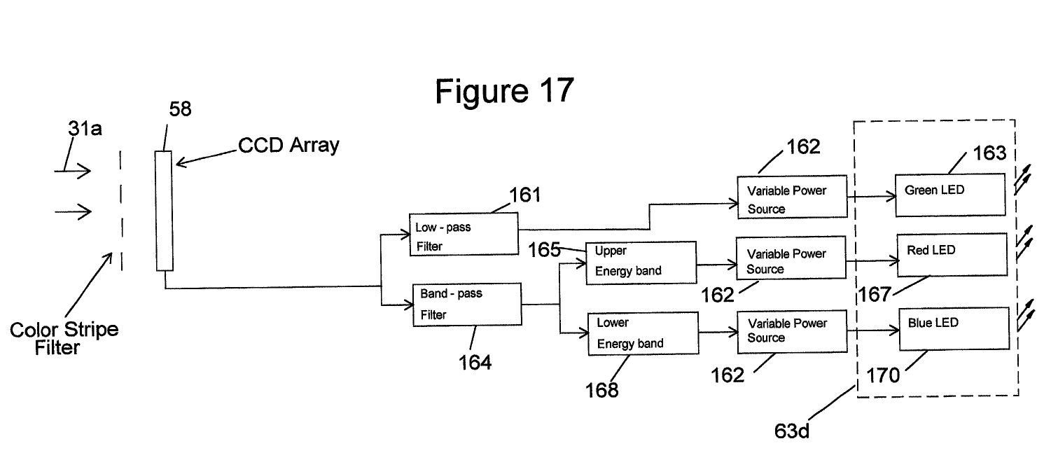

FIG. 17 illustrates a single two-dimensional pixel sending light in conjunction with a CCD receiver. This architecture supports the three-dimensional pixel described in FIG. 8b.

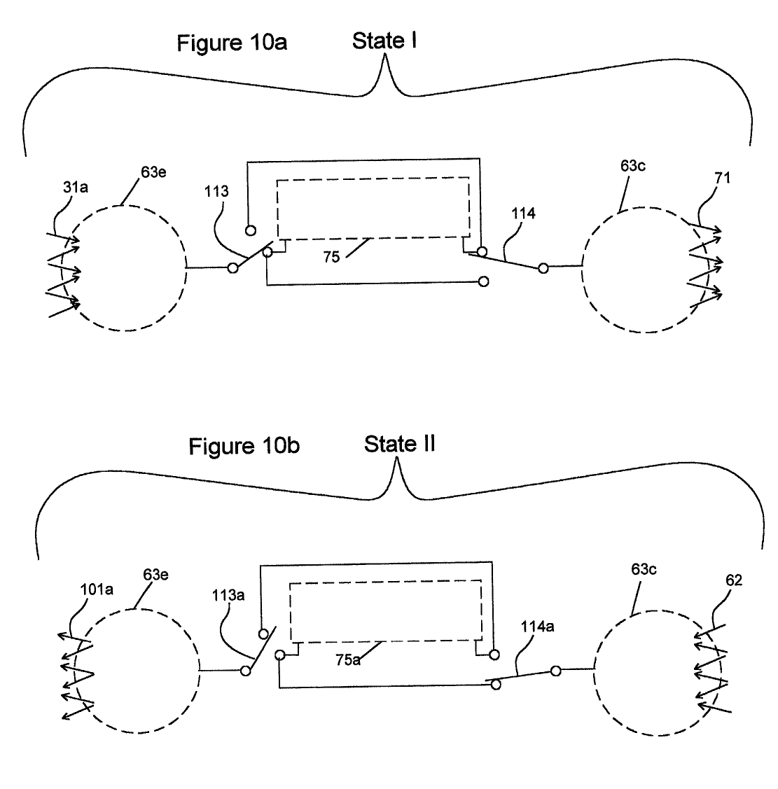

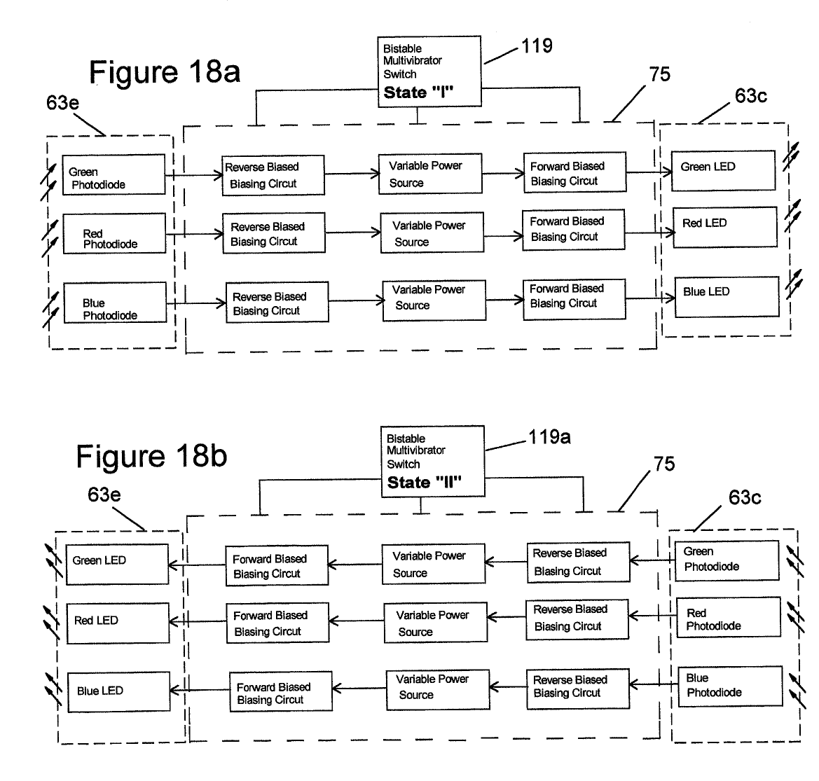

FIG. 18a shows a multi-state flow chart for FIG. 10a. A bistable multivibrator switch in state I 119 is specified as switching the circuit between State I and State II. This is similar to FIGS. 10a and 10b.

FIG. 18b shows a multi-state flow chart for FIG. 10b.

Second Embodiment—Light Pipe Implementation

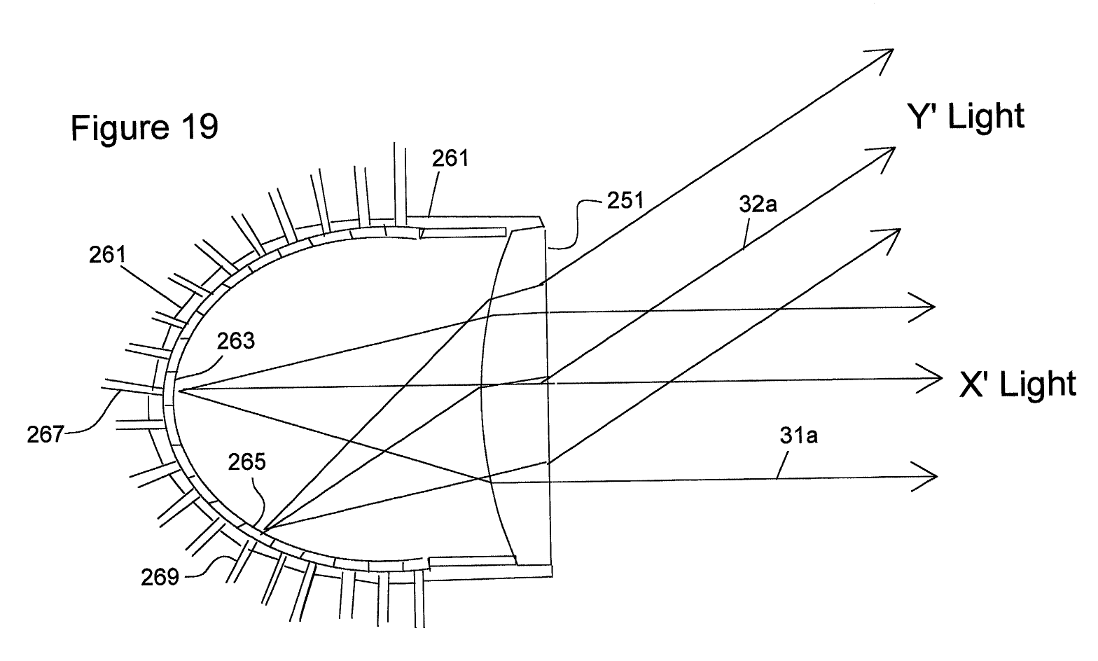

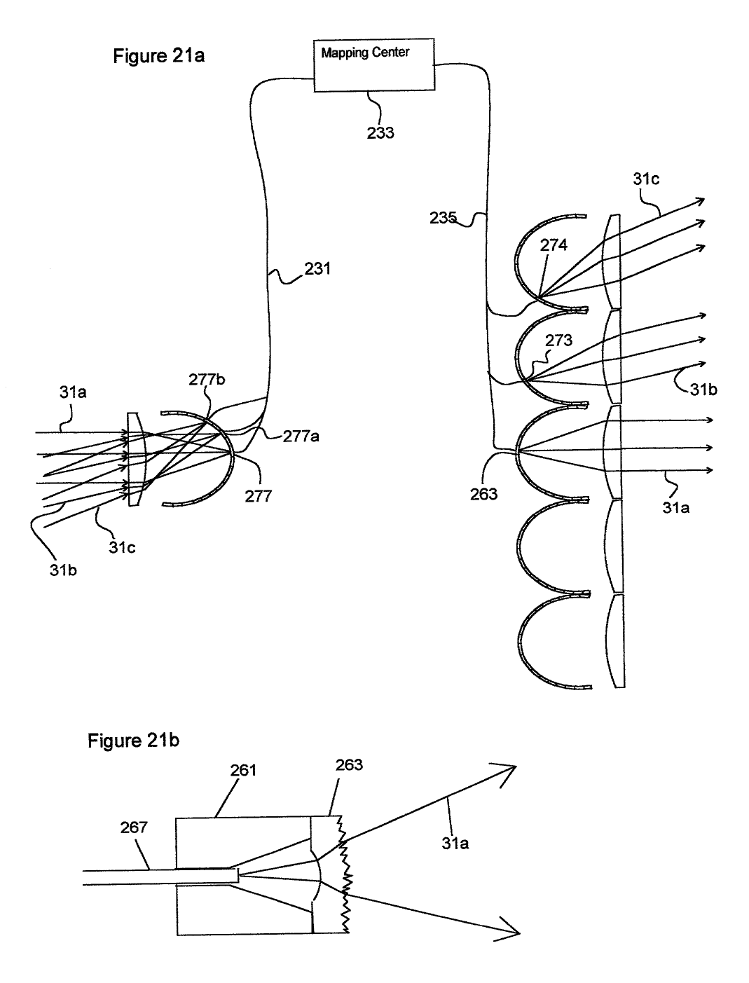

FIG. 19 illustrates a flexible light pipe pixel cell of the present invention in the second embodiment. A first hexagonal lens 251 divides light similarly to 51 as previously discussed. Located along the focal curve of 251 is a rigid focal curve substrate for light pipes 261. Mounted to the surface is a number of lenses similar to first focal curve light pipe injection lens 263 and second focal curve light pipe injection lens 265. A blown up light pipe injection lens is shown in FIG. 21b. The 263 is shown sending light from a first flexible light pipe 267, through 251 and out as 31a in the direction of X′. It should be noted that all light pipes send and receive light in exact opposite directions concurrently. Similarly, a second flexible light pipe 269 sends light through 265, which passes through 251 to become a light from second light pipe 32a (light sent in the Y′ direction). As will become apparent, the 31a and 32a light are examples of light that was incident upon the surfaces of other pixels and was transferred by flexible light pipes. Many such three-dimensional pixels operating cooperatively renders the asset invisible. One manufacture of flexible light pipes which are suitable for this application is Bivar, Inc. of Irvine, Calif., their off the shelf products have diameters which are excessive, but they have the capability to make smaller diameters suitable for use herein.

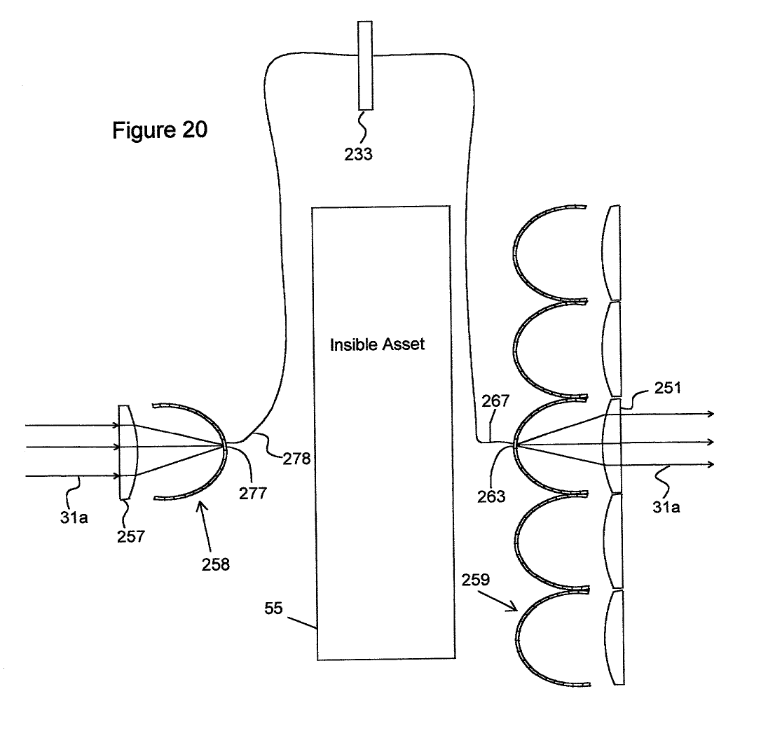

FIG. 20 illustrates two cooperating three-dimensional pixel segments in the second embodiment. 31a light which is received from a background trajectory is concentrated by a third focal curve light pipe injection lens 277 for injection into a third flexible light pipe 278. The 278 is patched into a 233 flexible light pipe map board such that it is paired with 267. Thus light that was incident upon 257 at the 31a trajectory reemerges across the surface of 251 as 31 a light. The 31a light emerges at its original trajectory, color, and intensity. The 233 provides a means to map flexible light pipes together in a rigid permanent relationship such that for example light incident upon 277 will always emerge from 263 and light incident upon 263 will always emerge from 277.

FIG. 21a illustrates multiple cooperating three-dimensional pixel segments in the second embodiment. 31b and 31c light have been added. They are incident respectively upon a fourth focal curve light pipe injection lens 277a and a fifth focal curve light pipe injection lens 277b. The 31b and 31c light emerges respectively from a sixth focal curve light pipe injection lens 273 and a seventh focal curve light pipe injection lens 274. Many thousands of such relationships cause observers to “see through” the cloaked asset.

FIG. 21b is a close-up of the sending/receiving injection surface architecture of the present invention in the second embodiment. The 267 is secured within the 261. Affixed to the face of 261 is the 263. 31a light emerging in a narrow field from 267 is spread by the 263 before being incident upon the entire surface of 251 (not shown). As previously stated, light goes exactly in the opposite direction concurrently.

The second embodiment can use any lens and lens focal curve or focal plane architecture that was described for the first embodiment.

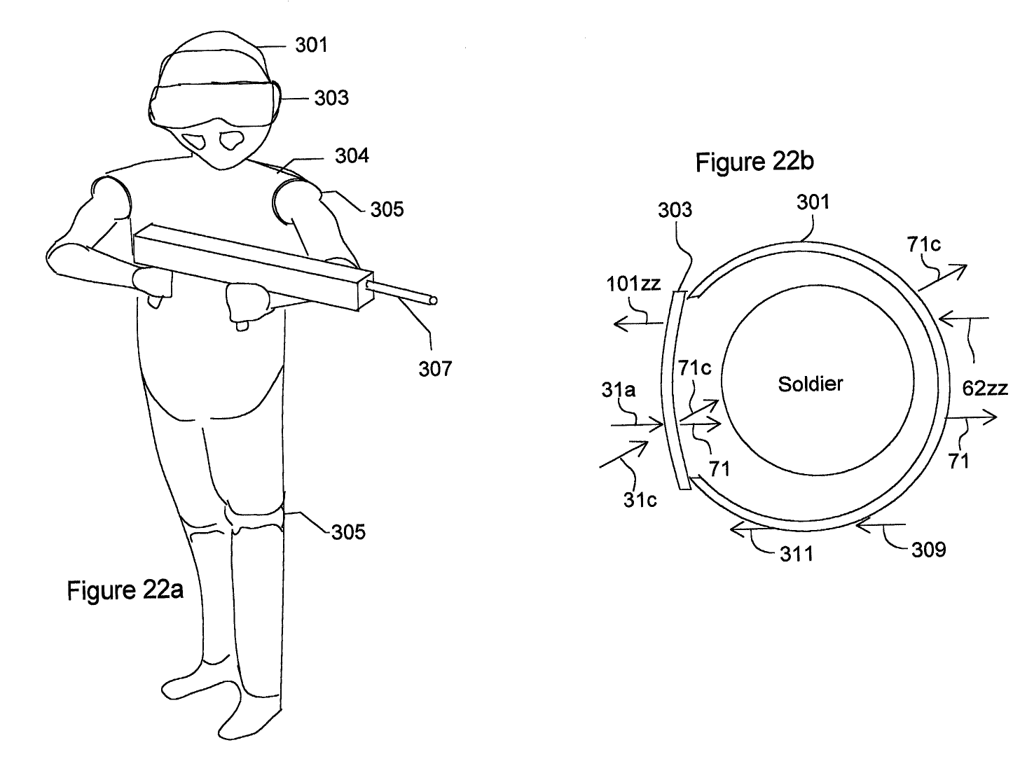

FIG. 22a is a soldier outfitted in a suit incorporating the present invention. The suit can be comprised of either electronic three-dimensional pixels and/or of flexible light pipe three-dimensional pixels. The former are preferable to enable a sensor joints 305 to sense the positions of movable parts relative to one another. This enables the 75 processor and logic to make arms and legs invisible even as they move relative to the rest of the cloaked assets. Thus rigid parts can flex while still being cloaked.

FIG. 22b is a cross section of the helmet and goggles of FIG. 22a The 31a and 31c enter a cloaking three-dimensional goggles 303. The goggles reproduce the sensed 31a and 31c on the inside of the goggles as 71 and 71c respectively. Thus the goggles provide a panoramic three-dimensional display means to the soldier. Since the 71 and the 71c are produced electronically, they can be amplified as desired, or they can transform the frequencies from non-visible parts of the spectrum to visible light. Note that to fulfill the cloaking means, a transparent helmet 301 also reproduces the 71 and the 71c on their original trajectories, colors, and intensities. Similarly a light received by helmet 62zz is sensed and a light emitted from cloaking goggles 101zz is produced to mimic its trajectory, color and intensity. Note that even an extreme off axis ray incident 309 is efficiently sense and mimicked as extreme off axis ray exit 311. This extreme off axis sensing and reproduction can be achieved in either the electronic or the flexible light pipe embodiments using the seven surfaced lens of FIG. 16a, 16b, and 16c.

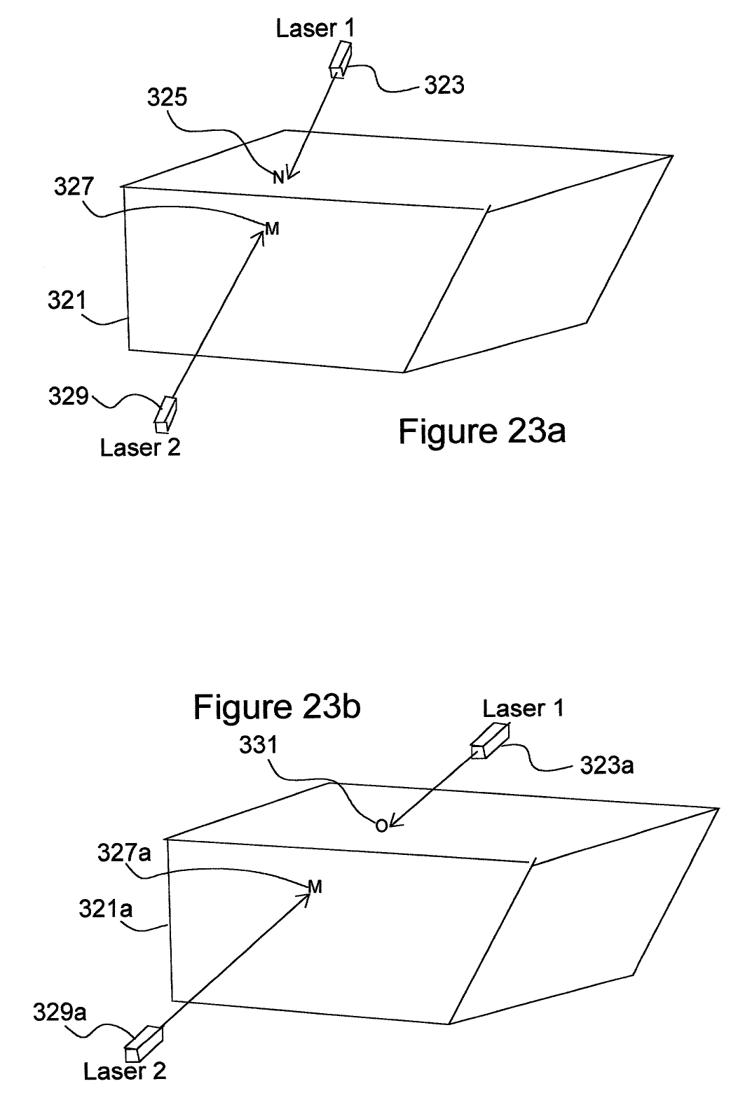

FIG. 23a and FIG. 23b illustrate a three-dimensional pixel cell relationship testing process. A first mapping laser 323 produces a light which is detected at a surface of a first corresponding three-dimensional pixel cell N 325. A second mapping laser 329 is detected on a surface within a three-dimensional pixel cell M 327. The beam of 323 is exactly opposite to that of 329. This tells us that (assuming a cloaked asset 321 is a rigid structure) a corresponding relationship exists between the surface of N and the surface of M. In the electronic embodiment, this relationship can be recorded in memory. In the flexible light pipe embodiment, this relationship can be hard wired by patching these two light pipes together on the 233.

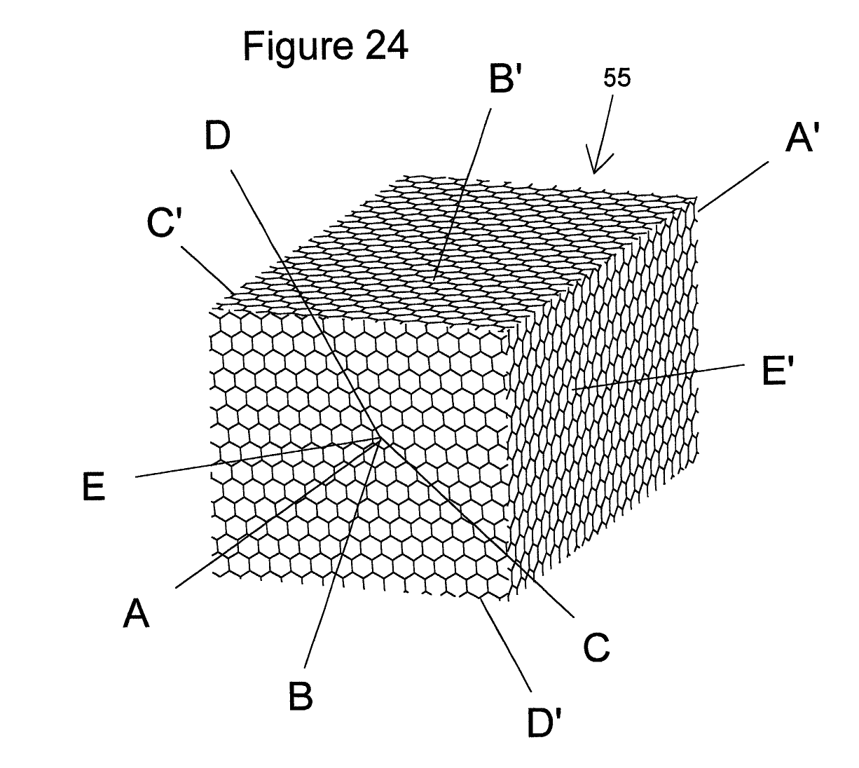

FIG. 24 illustrates the multiple surface relationships of a single pixel cell. Multi trajectory light is shown incident upon one three-dimensional pixel cell. A light will exit at A′ on a second surface, B at B′ on a third surface, C at C′ on a fourth surface, D at D′ on a fifth surface, and E at E′ prime on a sixth surface. Thus one three-dimensional pixel cell has corresponding relationships with all of the other surfaces of the cloaked asset. In practice, each single pixel cell may have relationships with all other pixel cells except those which are in a similarly facing parallel plane. The direction of all incident and exiting light operates in reverse direction as well.

Operation of the Invention

The second flexible light pipe embodiment has the advantage of being able to transfer full spectrum light in both directions concurrently with no energy input. The first electronic embodiment has the advantage of being able to produce displays (for occupants of the asset) from sensed information while concurrently producing cloaking from sensed information. Also it can be used as an unoccupied surveillance vehicle by recording and transmitting information about the electromagnetic energy it senses.

The preceding section also describes detailed operation of the invention.

Conclusion, Ramifications, and Scope

Thus the reader will see that the Three-Dimensional Receiving and Displaying Process and Apparatus With Military Application of this invention provides a highly functional and reliable means for using technology to conceal the presence of an object (or asset). This is achieved electronically in a first embodiment and optically in a second embodiment.

While the above description describes many specifications, these should not be construed as limitations on the scope of the invention, but rather as an exemplification of two preferred embodiments thereof, Many other variations are possible.

Lenses which enable wide angle light segmentation at the pixel level can be designed in many configurations and in series using multiple elements, shapes and gradient indices. Light can be directed by a lens to form a series of focal points along a focal plane instead of a along a focal curve. A fiber optic element with internal reflection or refraction means that performs substantially equivalently can replace a light pipe. Photodiodes and LED's can be replaced by other light detecting and light producing means respectively. The mapping means can consist of a simple plug which connects prefabricated (and pre-mapped) segmented pixel array components designed to fit onto a particular asset.

The electronic embodiment segmented pixel receiving array (trajectory specific Photo diode array) can be used as input for a video recording and storage means. (This is a novel camera application of the present invention.) The electronic embodiment segmented pixel sending array (trajectory specific LED array) can be used as an output means for displaying video images which enable multiple users in different positions to view different perspectives simultaneously on a single two-dimensional or three-dimensional video display device. Alternately, one or more viewers moving around relative to the display will see different images as they would moving around in the real world. (This is a novel video display application of the present invention.)

The flexible light pipe embodiment segmented pixel receiving array (trajectory specific fiber array) can be used as input for a video recording and storage means. (This is a novel camera application of the present invention.) The fiber optic embodiment segmented pixel sending array (trajectory specific fiber array) can be used as an output means for displaying video images which enable multiple users in different positions to view different perspectives simultaneously on a single video display device. Alternately, one viewer moving around relative to the display will see different images as they would moving around in the real world. (This is a novel video display application of the present invention.)

When the electronic embodiment is operating as a camera, a memory may be provided to store three-dimensional information received by the three-dimensional pixels. The receiving pixels described herein can form a three-dimensional camera without any cloaking function or sending pixels integrated therewith.

When the electronic embodiment is operating as a three-dimensional display, the visual information played may be drawn from a memory which must be provided for that purpose. The sending pixels described herein can form a three-dimensional display without any cloaking function or receiving pixels integrated therewith.

I claim:

1. A means for receiving a light beam on a first side of an object and for generating a corresponding light beam on a second side of said object, wherein said corresponding light beam is intended to resemble the received light beam in trajectory, color and intensity.

2. An array of lenses for receiving light from at least two trajectories and a second array of lenses for emitting light in at least two trajectories; wherein the receiving light trajectories are equivalent to the emitting light trajectories.

3. A means for receiving a light beam on a first side of an object at a first trajectory and for channeling it to a second side of said object, where it is released at the same said trajectory.
